(19) United States
(12) Patent Application Publication
(10) Pub. No.: US 2024/0222500 A1
(43) Pub. Date: Jul. 4, 2024

(54) SEMICONDUCTOR DEVICE AND METHOD OF MANUFACTURING SEMICONDUCTOR DEVICE

(71) Applicant: ROHM CO., LTD., Kyoto (JP)

(72) Inventor: Takeshi ISHIDA, Kyoto (JP)

(73) Assignee: ROHM CO., LTD., Kyoto (JP)

(21) Appl. No.: 18/389,990

(22) Filed: Dec. 20, 2023

(30) Foreign Application Priority Data
Dec. 28, 2022 (JP) 2022-212457

(51) Int. Cl. H01L 29/78; H01L 29/08; H01L 29/10; H01L 29/66

(52) U.S. Cl. CPC H01L 29/7816; H01L 29/086; H01L 29/0878; H01L 29/1095; H01L 29/66681

(57) ABSTRACT

A semiconductor device includes: a first conductivity type substrate; a second conductivity type semiconductor layer formed over the substrate; a second conductivity type drift region formed at a surface portion of the semiconductor layer; a second conductivity type drain region formed at the drift region; a first conductivity type body region formed adjacent to the drift region at the surface portion of the semiconductor layer; a second conductivity type source region formed at the body region; and a first conductivity type resurf layer that expands from a center of the drain region to both sides in a lateral direction along a main surface of the semiconductor device to entirely cover the drift region.

### CROSS-REFERENCE TO RELATED APPLICATION

This application is based upon and claims the benefit of priority from Japanese Patent Application No. 2022-212457, filed on Dec. 28, 2022, the entire contents of which are incorporated herein by reference.

### TECHNICAL FIELD

The present disclosure relates to a semiconductor device and a method of manufacturing the semiconductor device.

In the related art, there is disclosed a semiconductor device including a p-type well region that separates an element formation region, and a DMOS transistor formed in the element formation region. The semiconductor device includes a p-type silicon substrate, an n-type source region, and an n-type drain region selectively formed on the surface of the silicon substrate and separated from each other by a field oxide film, and a gate electrode formed on the silicon substrate with a gate oxide film interposed therebetween.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment of the present disclosure.

FIG. 2 is an enlarged view of region II shown in FIG. 1.

FIG. 3 is diagram showing a cross-sectional view taken along line III-III shown in FIG. 2.

FIGS. 4A and 4B are diagrams explaining effects of the semiconductor device according to the first embodiment of the present disclosure.

FIG. 5A is a diagram showing a part of a process of manufacturing the semiconductor device according to the first embodiment of the present disclosure.

FIG. 5B is a diagram showing a next step of FIG. 5A.

FIG. 5C is a diagram showing a next step of FIG. 5B.

FIG. 5D is a diagram showing a next step of FIG. 5C.

FIG. 5E is a diagram showing a next step of FIG. 5D.

FIG. 5F is a diagram showing a next step of FIG. 5E.

FIG. 5G is a diagram showing a next step of FIG. 5F.

FIG. 5H is a diagram showing a next step of FIG. 5G.

FIG. 5I is a diagram showing a next step of FIG. 5H.

FIG. 5J is a diagram showing a next step of FIG. 5I.

FIG. 5K is a diagram showing a next step of FIG. 5J.

FIG. 5L is a diagram showing a next step of FIG. 5K.

FIG. 5M is a diagram showing a next step of FIG. 5L.

FIG. 6 is a diagram corresponding to FIG. 3 and is a schematic cross-sectional view of a semiconductor device according to a second embodiment of the present disclosure.

FIG. 7A is a diagram showing a part of a process of manufacturing the semiconductor device according to the second embodiment of the present disclosure.

FIG. 7B is a diagram showing a next step of FIG. 7A.

FIG. 7C is a diagram showing a next step of FIG. 7B.

FIG. 7D is a diagram showing a next step of FIG. 7C.

FIG. 7E is a diagram showing a next step of FIG. 7D.

FIG. 7F is a diagram showing a next step of FIG. 7E.

FIG. 7G is a diagram showing a next step of FIG. 7F.

FIG. 7H is a diagram showing a next step of FIG. 7G.

FIG. 8 is a diagram corresponding to FIG. 3 and is a cross-sectional view for explaining a first modification of the present disclosure.

FIG. 9 is a diagram corresponding to FIG. 3 and is a cross-sectional view for explaining a second modification of the present disclosure.

FIG. 10 is a diagram corresponding to FIG. 3 and is a cross-sectional view for explaining a third modification of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

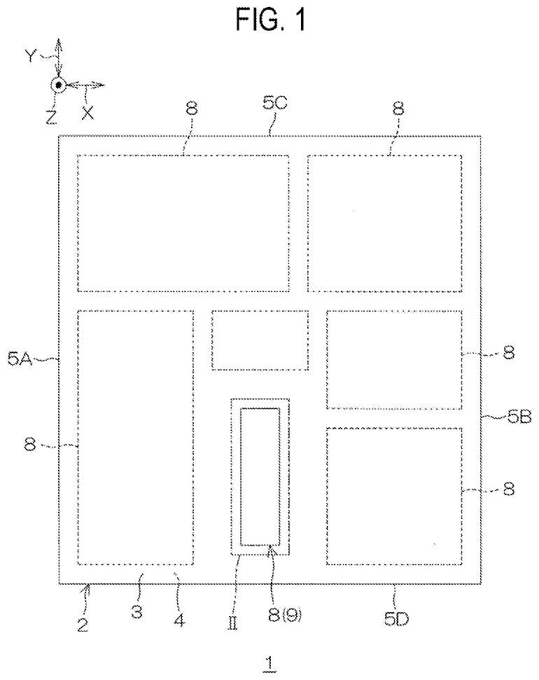

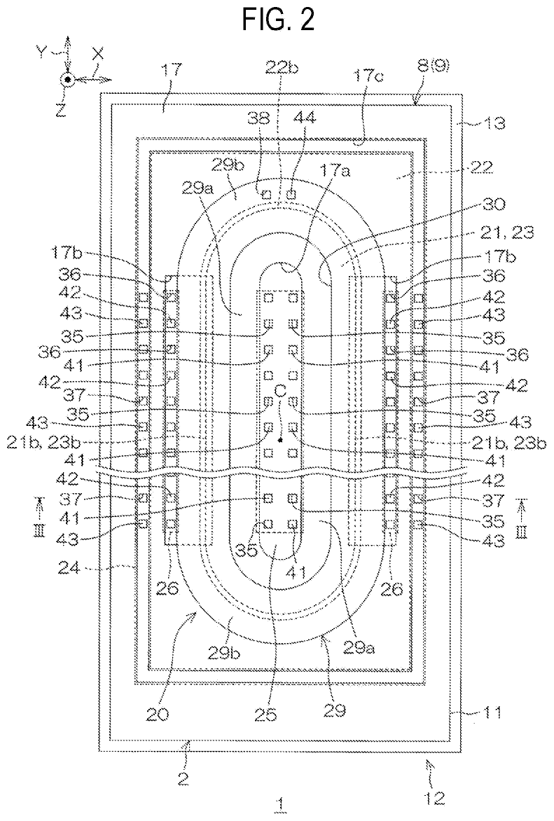

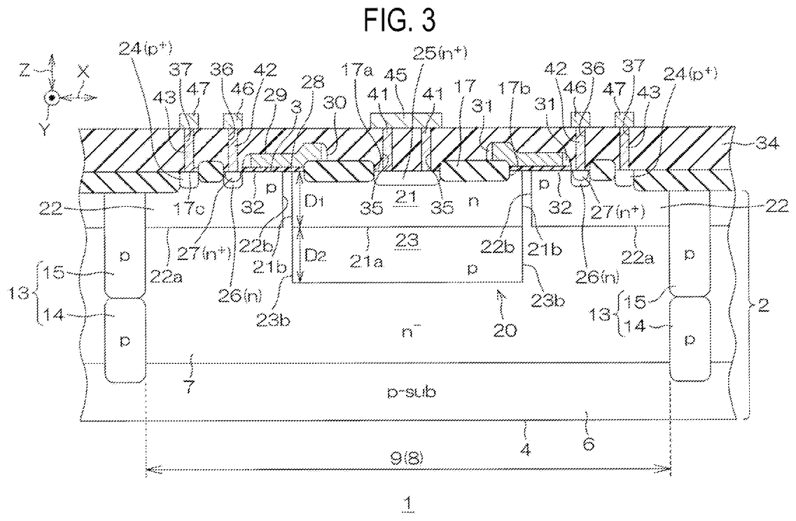

FIG. 1 is a schematic plan view of a semiconductor device 1 according to a first embodiment of the present disclosure. FIG. 2 is an enlarged view of region II shown in FIG. 1. FIG. 3 is a cross-sectional view taken along line III-III shown in FIG. 2.

As shown in FIGS. 1 to 3, the semiconductor device 1 includes a semiconductor chip 2 formed in a rectangular parallelepiped shape. The semiconductor chip 2 forms an outer shape of the semiconductor device 1 and is, for example, a structure in which a single crystal semiconductor material is formed into a chip shape (rectangular parallelepiped shape). The semiconductor chip 2 is made of a semiconductor material such as Si or SiC. The semiconductor chip 2 has a first main surface 3 on one side, a second main surface 4 on the other side, and first to fourth side surfaces 5A to 5D connecting the first main surface 3 and the second main surface 4.

The first main surface 3 and the second main surface 4 are formed into a square shape in a plan view when viewed from a normal direction Z thereof (hereinafter simply referred to as “plan view”). The first main surface 3 is a device surface on which functional devices are formed. The second main surface 4 is a non-device surface on which no functional device is formed. In this embodiment, the semiconductor chip 2 may include at least one of a semiconductor substrate and an epitaxial layer.

The first to fourth side surfaces 5A to 5D include a first side surface 5A, a second side surface 5B, a third side surface 5C, and a fourth side surface 5D. The third side surface 5C and the fourth side surface 5D extend in a first direction X and face each other in a second direction Y orthogonal to the first direction X. The first side surface 5A and the second side surface 5B extend in the second direction Y and face each other in the first direction X.

As shown in FIG. 3, the semiconductor chip 2 includes a p-type (first conductivity type) substrate 6. In this embodiment, the p-type substrate 6 is a semiconductor substrate, more specifically a silicon substrate. The substrate 6 forms an entire surface portion of the second main surface 4. The p-type substrate 6 is exposed at the second main surface 4 and the first to fourth side surfaces 5A to 5D. A concentration of p-type impurity (first impurity) in the substrate 6 may be 1.0×10¹³ cm⁻³ or more and 1.0×10¹⁵ cm⁻³ or less. A thickness of the p-type substrate 6 may be 100 μm or more and 1,000 μm or less.

The semiconductor chip 2 includes an n-type (second conductivity type) semiconductor layer 7 formed over the substrate 6. In this embodiment, the semiconductor layer 7 is an n-type epitaxial layer. In this embodiment, the n-type semiconductor layer 7 is in direct contact with the substrate 6. A concentration of n-type impurity (second impurity) in the semiconductor layer 7 may be 1.0×10¹⁴ cm⁻³ or more and 1.0×10¹⁶ cm⁻³ or less. The n-type semiconductor layer 7 is formed over an entire surface portion of the first main surface 3 and is exposed at the first main surface 3 and the first to fourth side surfaces 5A to 5D. A thickness of the n-type semiconductor layer 7 is smaller than a thickness of the substrate 6, for example. A thickness of the semiconductor layer 7 may be 5 μm or more and 20 μm or less. Note that since the n-type semiconductor layer 7 has a relatively low impurity concentration, it may also be referred to as an n⁻-type region.

An element isolation well 13 is formed in the n-type semiconductor layer 7. The element isolation well 13 is, for example, formed in an annular shape in a plan view. The element isolation well 13 is not limited thereto and may have another closed curve structure such as a circular annular shape or a triangular annular shape in a plan view

As shown in FIG. 3, the element isolation well 13 may have a two-layer structure including a p-type first pillar region 14 formed near the second main surface 4 and a second pillar region 15 formed near the first main surface 3. A boundary between the first pillar region 14 and the second pillar region 15 of the element isolation well 13 is set in the semiconductor layer 7. The boundary between the first pillar region 14 and the second pillar region 15 may be set at a depth of 1.0 μm or more and 10 μm or less from the first main surface 3 of the semiconductor chip 2, for example.

A plurality of device regions 8 are partitioned in the semiconductor layer 7 by the element isolation well 13. The number and arrangement of the plurality of device regions 8 are arbitrary. The plurality of device regions 8 may include functional devices formed using the surface portion of the first main surface 3. The functional device may include, for example, at least one selected from the group of a semiconductor switching device, a semiconductor rectifying device, and a passive device. The functional device may include, for example, a circuit network combining at least two selected from the group of the semiconductor switching device, the semiconductor rectifying device, and the passive device.

The semiconductor switching device may include, for example, at least one selected from the group of a MOSFET (Metal Oxide Semiconductor Field Effect Transistor), a BJT (Bipolar Junction Transistor), an IGBT (Insulated Gate Bipolar Junction Transistor), and a JFET (Junction Field Effect Transistor). The semiconductor rectifying device may include, for example, at least one selected from the group of a pn junction diode, a pin junction diode, a Zener diode, a Schottky barrier diode, and a fast recovery diode. The passive device may include, for example, at least one selected from the group of a resistor, a capacitor, and an inductor.

The plurality of device regions 8 include an LDMOS region 9 in which an LDMOSFET (Lateral Double Diffused MOSFET) 20 is formed (see the region II in FIG. 1) as an example of the MOSFET. A structure of the LDMOS region 9 is explained below in detail.

A field insulating film 17 is formed over the first main surface 3 of the semiconductor chip 2. As shown in FIG. 3, the field insulating film 17 partially overlaps the element isolation well 13 and is selectively formed in an inner region of the element isolation well 13. The field insulating film 17 may be, for example, a LOCOS film formed by selectively oxidizing the surface (first main surface 3) of the semiconductor layer 7.

The field insulating film 17 has a first opening 17a, a second opening 17b, and a third opening 17c. As shown in FIG. 2, the first opening 17a is formed in an elliptical shape that extends long in the second direction Y in a plan view. The second opening 17b is formed in a rectangular shape that extends long in the second direction Y in a plan view. In the first direction X, a pair of second openings 17b may be formed to sandwich the first opening 17a. The third opening 17c is formed in a square annular shape along the first direction X and the second direction Y in a plan view. The third opening 17c may be formed to surround the first opening 17a and the pair of second openings 17b.

The LDMOSFET 20 is formed in the LDMOS region 9. As shown in FIG. 3, an n-type (second conductivity type) drift region 21 is formed at a surface portion of the semiconductor layer 7. The n-type drift region 21 is formed in an elongated shape along the second direction Y in a plan view. The n-type drift region 21 has a higher n-type impurity concentration than the n-type semiconductor layer 7. The n-type impurity concentration of the n-type drift region 21 may be, for example, 1.0×10¹⁶ cm⁻³ or more and 1.0×10¹⁸ cm⁻³ or less.

An n-type drain region 25 is formed at a surface portion of the n-type drift region 21. The n-type drain region 25 may have a higher n-type impurity concentration than the n-type drift region 21. The n-type impurity concentration of the drain region 25 may be, for example, 1.0×10¹⁸ cm⁻³ or more and 1.0×10²² cm⁻³ or less. The n-type drain region 25 has an elongated shape along the second direction Y, as shown in FIG. 2. The n-type drain region 25 is exposed from the field insulating film 17 at the first opening 17a.

A p-type (first conductivity type) body region 22 is formed adjacent to the n-type drift region 21 at the surface portion of the semiconductor layer 7. As shown in FIG. 2, the p-type body region 22 is formed in an annular shape in a plan view so as to surround the n-type drift region 21. The p-type body region 22 sandwiches the n-type drift region 21 in the first direction X. The p-type body region 22 may have a higher p-type impurity concentration than the p-type substrate 6. The p-type impurity concentration of the p-type body region 22 may be, for example, 1.0×10¹⁶ cm⁻³ or more and 1.0×10¹⁸ cm⁻³ or less.

In this embodiment, as shown in FIG. 3, the n-type drift region 21 and the p-type body region 22 are formed at intervals in the first direction X. The p-type body region 22 is formed at an interval in the first direction X from the n-type drain region 25. A bottom 22a of the p-type body region 22 is located at the same depth as a bottom 21a of the n-type drift region 21 in a thickness direction (normal direction Z) of the substrate 6. That is, a distance from the first main surface 3 to the bottom 22a of the body region 22 and a distance from the first main surface 3 to the bottom 21a of the drift region 21 may be the same. The distance from the first main surface 3 to the bottom 22a of the body region 22 may be smaller or larger than the distance from the first main surface 3 to the bottom 21a of the drift region 21.

An n-type source region 26 is formed at a surface portion of the p-type body region 22. The n-type source region 26 has a higher impurity concentration than the n-type semiconductor layer 7. The n-type source region 26 may have a strip shape along the second direction Y, as shown in FIG. 2. Referring to FIG. 3, an n-type high concentration portion 27 having a higher impurity concentration than the n-type source region 26 is formed at a surface portion of the n-type source region 26.

A p-type contact region 24 is formed at the surface portion of the p-type body region 22. The p-type contact region 24 may have a higher impurity concentration than the p-type body region 22. The p-type impurity concentration of the contact region 24 may be, for example, 1.0×10¹⁸ cm⁻³ or more and 1.0×10²² cm⁻³ or less. For example, as shown in FIG. 2, the p-type contact region 24 may have an annular shape surrounding the drain region 25 and the source region 26 in a plan view.

The LDMOSFET 20 includes a p-type resurf layer 23. The p-type resurf layer 23 is formed near the second main surface 4 with respect to the n-type drift region 21. The p-type resurf layer 23 expands from a center C of the n-type drain region 25 to both sides in a lateral direction along the first main surface 3 to entirely cover the n-type drain region 25.

Referring to FIG. 2, the center C of the drain region 25 may be, for example, a point at which centers of the drain region 25 in the first direction X and the second direction Y coincide. The resurf layer 23 expands along the first main surface 3 from the center C over an entire periphery thereof. The resurf layer 23 expands from the center C to a region outside a peripheral edge of the drain region 25 in a plan view. As a result, the drain region 25 is surrounded all around by the resurf layer 23 in a plan view.

The p-type resurf layer 23 may be in contact with the n-type drift region 21. As shown in FIG. 2, the p-type resurf layer 23 is formed in an elongated shape along the second direction Y in a plan view. The p-type resurf layer 23 and the n-type drift region 21 are overlapping in a plan view.

A side portion 23b of the p-type resurf layer 23 and a side portion 21b of the n-type drift region 21 are flush with each other. In other words, the side portion 23b of the p-type resurf layer 23 and the side portion 21b of the n-type drift region 21 are continuous in the thickness direction (normal direction Z) of the substrate 6. In the present disclosure, “continuous in the thickness direction of the substrate” means that there is no level difference in the lateral direction along the main surface of the substrate (first main surface 3 of the substrate 6). The side portion 23b of the p-type resurf layer 23 and the side portion 21b of the n-type drift region 21 may be in contact with each other or may be separated from each other. As a result, the side portion 23b of the resurf layer 23 is located between the drain region 25 and the source region 26.

The p-type resurf layer 23 is separated from the p-type body region 22. FIG. 3 shows a configuration in which the resurf layer 23 and the body region 22 are separated from each other in the first direction X. Referring to FIG. 2, the resurf layer 23 is surrounded by the body region 22 of the annular shape in a plan view. The side portion 23b of the resurf layer 23 is formed in an annular shape along a side portion 22b of the body region 22, spaced at a substantially constant distance from the side portion 22b of an annular shape inside the body region 22.

The p-type resurf layer 23 may have a higher p-type impurity concentration than the p-type substrate 6. The p-type impurity concentration of the p-type resurf layer 23 may be, for example, 1.0×10¹⁶ cm⁻³ or more and 1.0×10¹⁸ cm⁻³ or less. A thickness D₂ of the p-type resurf layer 23 may be larger than a thickness D₁ of the n-type drift region 21, for example.

As shown in FIG. 3, a gate insulating film 28 is formed over the first main surface 3 at the second opening 17b of the field insulating film 17. The gate insulating film 28 is formed so as to straddle the n-type drift region 21 and the body region 22 with the semiconductor layer 7 in between. The contact region 24 is exposed from the gate insulating film 28. The gate insulating film 28 may be, for example, a silicon oxide film formed by thermally oxidizing the first main surface 3. Further, a thickness of the gate insulating film 28 may be, for example, 0.01 μm or more and 1.0 μm or less.

A gate electrode 29 is formed at the first main surface 3 with the gate insulating film 28 interposed therebetween. In this embodiment, the gate electrode 29 is formed in an annular shape in a plan view so as to surround the drain region 25, as shown in FIG. 2. More specifically, the gate electrode 29 is formed in an elongated annular shape that integrally includes a pair of side portions 29a extending along the second direction Y and a pair of end portions 29b connecting the pair of side portions 29a. An opening 30 exposing the drain region 25 is formed in a center of the gate electrode 29. The opening 30 is formed in an elongated shape along the second direction Y.

The gate electrode 29 is formed to selectively cover the gate insulating film 28 and the field insulating film 17. The gate electrode 29 may contain a conductive material such as polysilicon or aluminum. The thickness of the gate electrode 29 may be, for example, 0.1 μm or more and 1.0 μm or less. A sidewall of the gate electrode 29 is covered with a sidewall 31 which is an insulating film.

Referring to FIG. 3, a portion of the body region 22 that the gate electrode 29 faces via the gate insulating film 28 is a channel region 32 of the LDMOSFET 20. Formation of a channel in the channel region 32 is controlled by the gate electrode 29.

An interlayer insulating film 34 is formed over the first main surface 3 so as to cover the gate electrode 29 and the field insulating film 17. The interlayer insulating film 34 is formed of, for example, an insulating film containing at least one selected from the group of an oxide film and a nitride film. Note that the interlayer insulating film 34 may be formed of a plurality of layers of interlayer insulating films.

A drain opening 35, a source opening 36, a back gate opening 37, and a gate opening 38 are formed in the interlayer insulating film 34. The drain opening 35, the source opening 36, and the back gate opening 37 penetrate the interlayer insulating film 34 in its thickness direction (normal direction Z).

The drain opening 35 is formed at a position overlapping the drain region 25 in a plan view. As shown in FIG. 2, the drain opening 35 may include a plurality of drain openings 35 arranged along the second direction Y. The plurality of drain openings 35 may be arranged along the second direction Y in two rows aligned in the first direction X, as shown in FIG. 2. Each drain opening 35 may have a square shape in a plan view. Further, although not illustrated, the drain opening 35 may include one long drain opening 35 along the second direction Y. A drain contact electrode 41 is formed inside the drain opening 35. The drain contact electrode 41 is connected to the drain region 25.

The source opening 36 is formed at a position overlapping the n-type source region 26 in a plan view. The source opening 36 may include a plurality of source openings 36 arranged along the second direction Y. A source contact electrode 42 is formed inside the source opening 36. Further, the source contact electrode 42 is connected to the n-type source region 26.

The back gate opening 37 is formed at a position overlapping the contact region 24 in a plan view. The back gate opening 37 may include a plurality of back gate openings 37 arranged along the second direction Y. A back gate contact electrode 43 is formed inside the back gate opening 37. The back gate contact electrode 43 is connected to the contact region 24.

The gate opening 38 is formed at a position overlapping the gate electrode 29 in a plan view. The gate opening 38 may include one or more gate openings 38 (two gate openings 38 in the example of FIG. 2) arranged at the end portions 29b of the gate electrode 29. A gate contact electrode 44 is formed inside the gate opening 38. The gate contact electrode 44 is connected to the gate electrode 29.

The drain contact electrode 41, the source contact electrode 42, the back gate contact electrode 43, and the gate contact electrode 44 are made of tungsten (W) in this embodiment, but may be made of other conductive materials (for example, aluminum (Al), copper (Cu), or the like). Needless to say, a barrier layer such as TiN may be used in this case.

A drain wiring 45, a source wiring 46, a back gate wiring 47, and a gate wiring (not shown) are formed on the interlayer insulating film 34. The drain wiring 45 is connected to the drain contact electrode 41. The source wiring 46 is connected to the source contact electrode 42. The back gate wiring 47 is connected to the back gate contact electrode 43. Further, the gate wiring is connected to the gate contact electrode 44.

The drain wiring 45, the source wiring 46, the back gate wiring 47, and the gate wiring may have a stacked structure including a Ti-based metal film, an Al-based metal film, and a Ti-based metal film. The Al-based metal film may include at least one selected from the group of a pure Al film (an Al film with a purity of 99% or more), an AlSi alloy film, an AlCu alloy film, and an AlSiCu alloy film.

The drain wiring 45 is electrically connected to the drain region 25 via the drain contact electrode 41. The source wiring 46 is electrically connected to the n-type source region 26 via the source contact electrode 42. The back gate wiring 47 is electrically connected to the contact region 24 via the back gate contact electrode 43. The gate wiring (not shown) is electrically connected to the gate electrode 29 via the gate contact electrode 44.

An on-resistance of the semiconductor device 1 and a breakdown voltage of the semiconductor device 1 (element breakdown voltage of the LDMOSFET 20) are inversely related to the n-type impurity concentration of the n-type drift region 21. Specifically, when the n-type impurity concentration of the n-type drift region 21 is increased, the on-resistance may be reduced, but the breakdown voltage of the semiconductor device 1 decreases. On the other hand, when the n-type impurity concentration of the n-type drift region 21 is reduced, a high breakdown voltage of the semiconductor device 1 may be achieved, but the on-resistance increases.

According to the semiconductor device 1, the p-type resurf layer 23 covering the n-type drift region 21 is formed. The side portion 23b of the p-type resurf layer 23 and the side portion 21b of the n-type drift region 21 are flush with each other (the side portion 23b of the p-type resurf layer 23 and the side portion 21b of the n-type drift region 21 are continuous in the thickness direction (normal direction Z) of the substrate 6). In other words, the p-type resurf layer 23 expands from a center C of the n-type drift region 21 to both sides in the lateral direction along the first main surface 3 to entirely cover the n-type drift region 21. By forming such a p-type resurf layer 23, it is possible to prevent electric field concentration from occurring in the n-type drain region 25. As a result, a high breakdown voltage of the semiconductor device 1 may be realized.

Therefore, even if the n-type impurity concentration of the n-type drift region 21 is increased, the breakdown voltage of the semiconductor device 1 may be maintained high. In this embodiment, the n-type impurity concentration of the n-type drift region 21 is set to be high (for example, 1.0×10¹⁷ cm⁻³ or more and 1.0×10¹⁸ cm⁻³ or less). By increasing the n-type impurity concentration of the n-type drift region 21, the on-resistance can be reduced. As a result, it is possible to reduce the on-resistance while maintaining the high breakdown voltage of the semiconductor device 1.

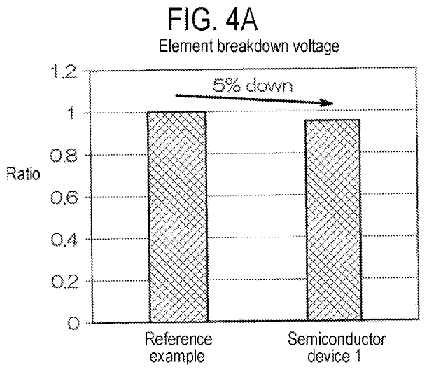

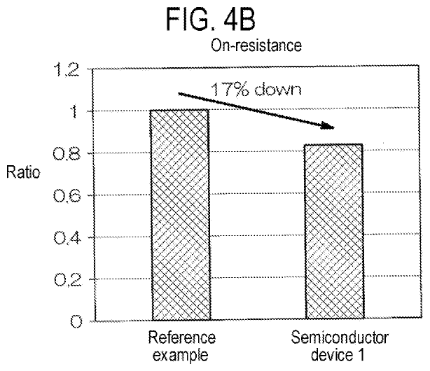

FIGS. 4A and 4B are diagrams for explaining effects of the semiconductor device 1 according to the first embodiment of the present disclosure. FIGS. 4A and 4B compare element breakdown voltages and on-resistance between the semiconductor device 1 and a semiconductor device according to a reference example, respectively. In FIGS. 4A and 4B, the element breakdown voltage and the on-resistance of the semiconductor device according to the reference example are set to 1, and the element breakdown voltage and the on-resistance of the semiconductor device 1 are expressed as relative values to the element breakdown voltage and the on-resistance of the semiconductor device according to the reference example.

The semiconductor device according to the reference example differs from the semiconductor device 1 in that the former does not include the p-type resurf layer 23. In the semiconductor device according to the reference example, the n-type impurity concentration of the n-type drift region 21 is 5.0×10¹⁶ cm⁻³ in order to maintain a high breakdown voltage. The semiconductor device according to the reference example includes the same configuration as the configuration of the semiconductor device 1 except for the n-type impurity concentration of the n-type drift region 21 and the presence or absence of the resurf layer 23.

Since the semiconductor device 1 includes the p-type resurf layer 23, the breakdown voltage may be maintained high even if the n-type impurity concentration of the n-type drift region 21 is higher than that of the semiconductor device according to the reference example. In the example of FIGS. 4A and 4B, the n-type impurity concentration of the n-type drift region 21 is, for example, 2.0×10¹⁷ cm⁻³. In this case, as shown in FIG. 4A, while the reduction in the breakdown voltage of the semiconductor device 1 is kept to 5% as compared to the semiconductor device according to the reference example, as shown in FIG. 4B, the on-resistance is significantly reduced (17%). It can be seen from FIGS. 4A and 4B that it is possible to reduce the on-resistance while maintaining a high breakdown voltage in the semiconductor device 1.

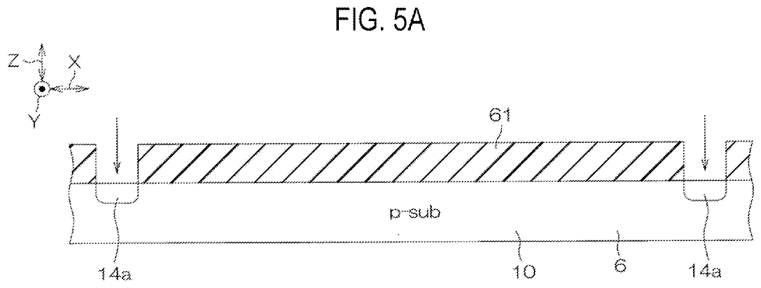

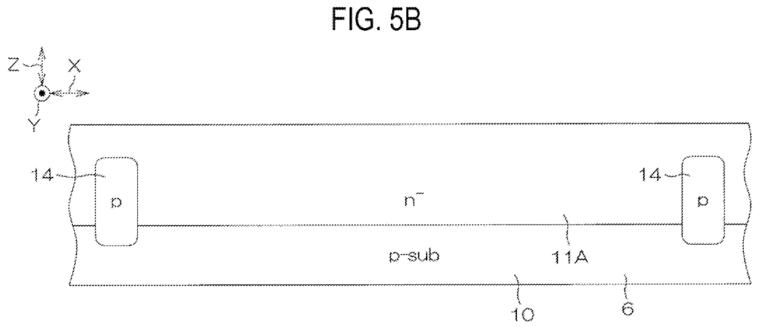

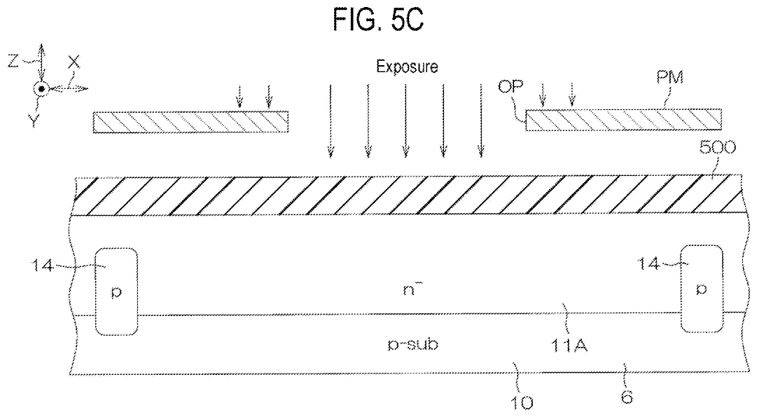

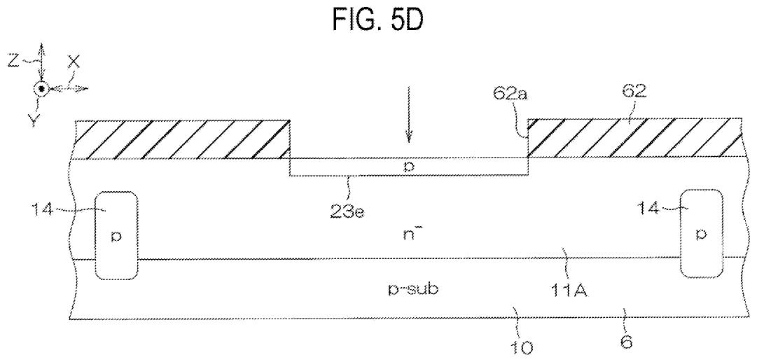

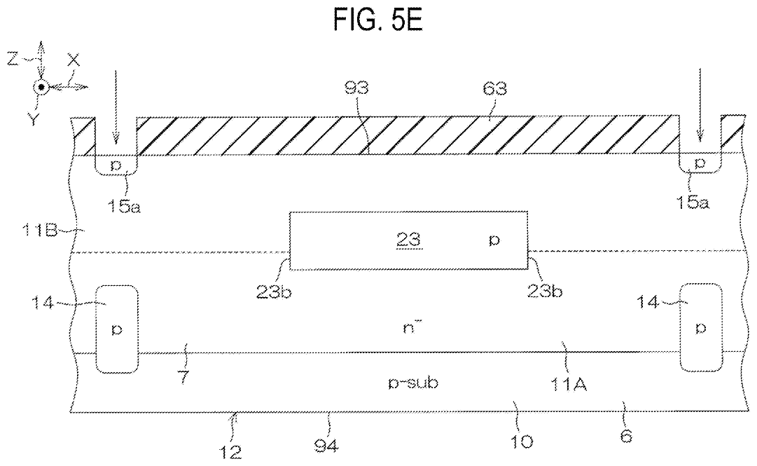

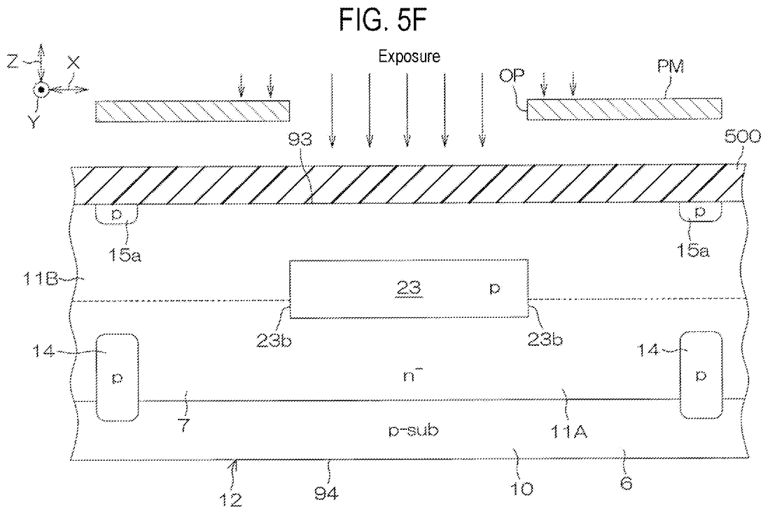

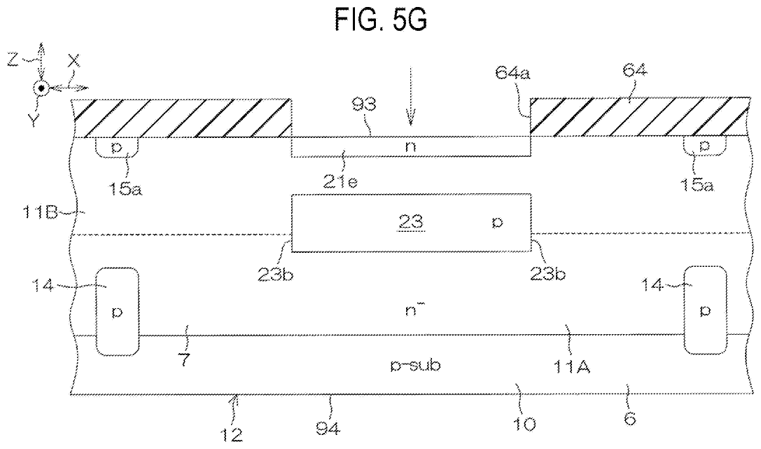

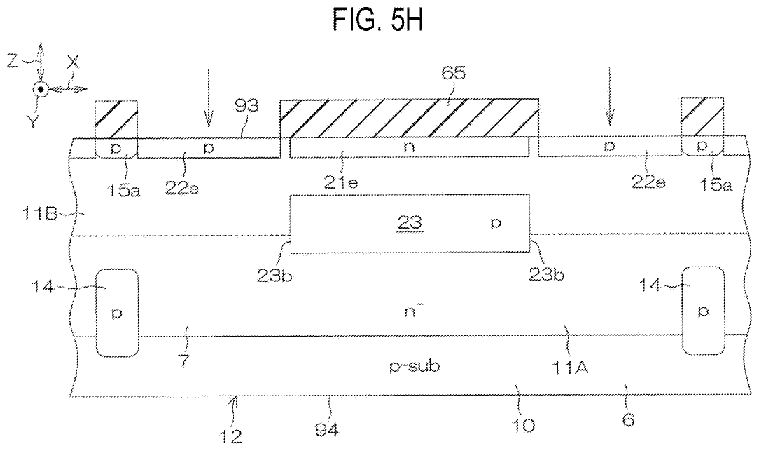

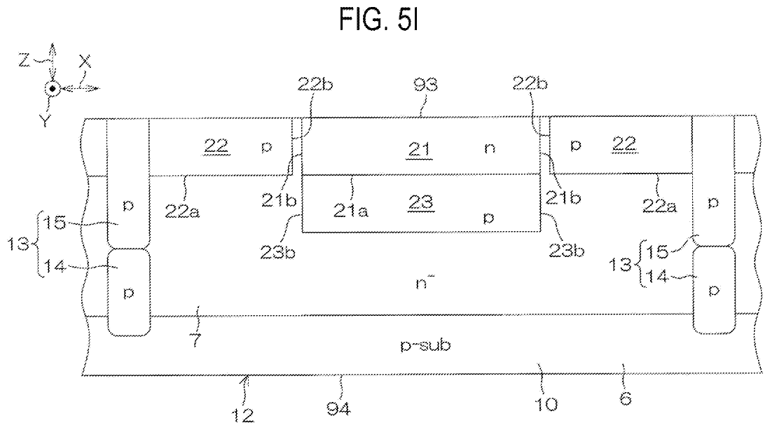

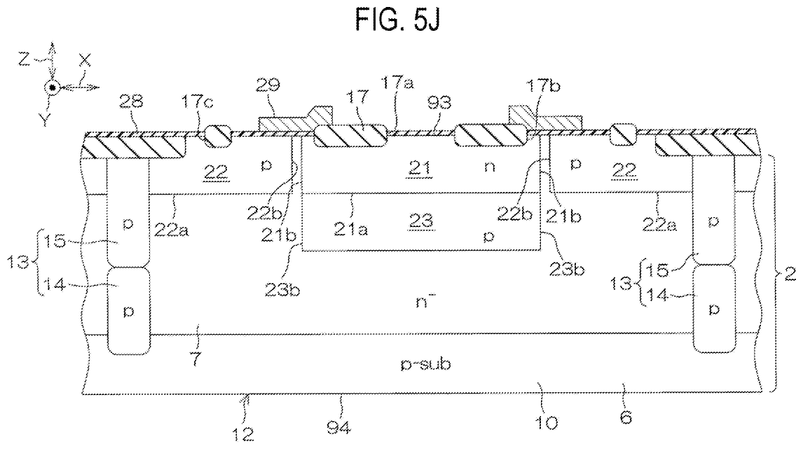

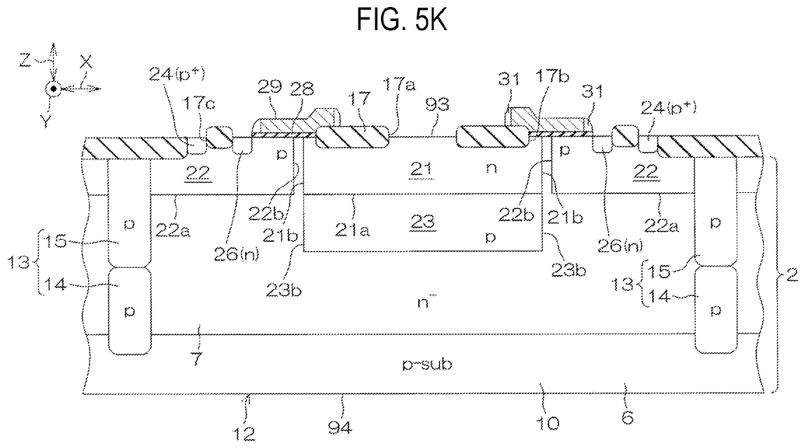

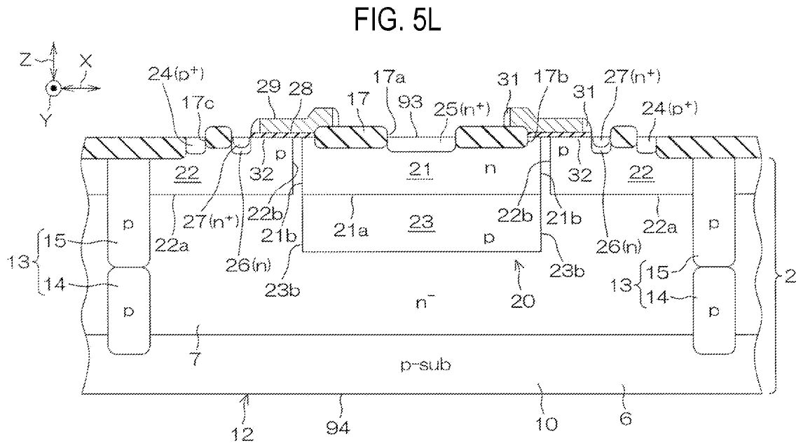

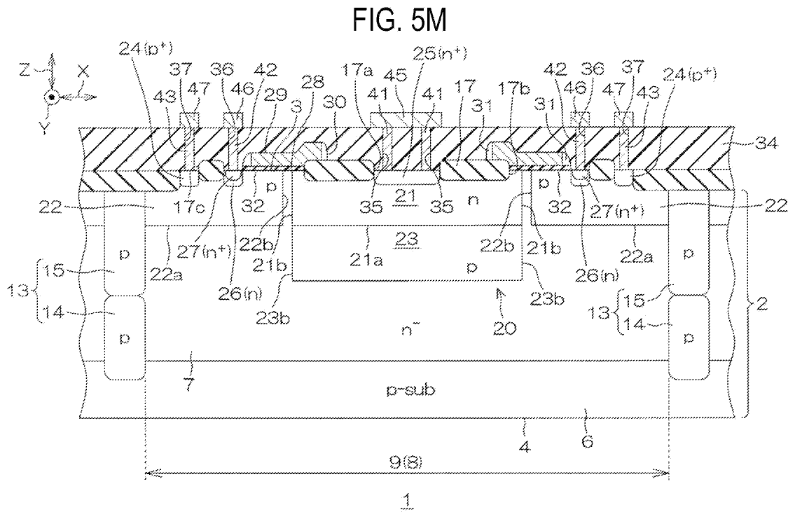

FIGS. 5A to 5M are diagrams showing parts of a process of manufacturing the semiconductor device 1 according to the first embodiment of the present disclosure. Note that in FIGS. 5A to 5M, among the reference numerals shown in FIG. 3, reference numerals for components necessary for explaining the process of manufacturing the semiconductor device 1 are mainly used, and other reference numerals may be omitted.

As shown in FIG. 5A, a p-type semiconductor wafer 10 is prepared. Planned cutting lines of device regions are set on the semiconductor wafer 10 to partition regions that will become individual semiconductor devices 1. The semiconductor wafer 10 corresponds to the substrate 6 of the semiconductor device 1. Next, a p-type impurity is selectively introduced into a surface portion of a main surface of the semiconductor wafer 10 through a first resist mask 61. As a result, a first introduction portion 14a is formed at the surface portion of the main surface of the semiconductor wafer 10. Thereafter, the first resist mask 61 is removed from the semiconductor wafer 10. Examples of the p-type impurity (first impurity) may include B (boron), Al (aluminum), and the like.

Next, as shown in FIG. 5B, a semiconductor material, such as Si or SiC, is epitaxially grown from the main surface of the semiconductor wafer 10 by an epitaxial growth method to form an n-type first epitaxial layer 11A. At this time, the p-type impurity of the first introduction portion 14a introduced into the main surface of the semiconductor wafer 10 diffuses into the n-type first epitaxial layer 11A. As a result, a p-type first pillar region 14 is formed.

Next, a second resist mask 62 (first mask) is placed on the first epitaxial layer 11A. In detail, as shown in FIG. 5C, a resist 500 is applied on the first epitaxial layer 11A, and a patterning mask PM is placed on the resist 500. The patterning mask PM has a predetermined opening pattern OP. By irradiating the resist 500 with light (for example, ultraviolet light, etc.) through the patterning mask PM, the resist 500 is exposed, and a portion of the resist 500 exposed through the opening pattern OP is removed. As a result, as shown in FIG. 5D, the second resist mask 62 with an opening 62a having the same pattern as the opening pattern OP of the patterning mask PM is formed. The opening 62a of the second resist mask 62 corresponds to a region where the p-type resurf layer 23 is to be formed. The patterning mask PM is retracted from above the first epitaxial layer 11A.

Next, as shown in FIG. 5D, a p-type impurity is selectively introduced into the surface portion of the first epitaxial layer 11A through the second resist mask 62. As a result, a second introduction portion 23e is formed at the surface portion of the main surface of the semiconductor wafer 10. Thereafter, the second resist mask 62 is removed from the semiconductor wafer 10.

Next, as shown in FIG. 5E, a semiconductor material, such as Si or SiC, is epitaxially grown from a main surface of the first epitaxial layer 11A by an epitaxial growth method to form an n-type second epitaxial layer 11B. At this time, the p-type impurity of the second introduction portion 23e introduced into the main surface of the semiconductor wafer 10 diffuses into the second epitaxial layer 11B in the thickness direction (normal direction Z) of the substrate 6. As a result, the p-type resurf layer 23 is formed. A surface of the p-type resurf layer 23 (the surface on an opposite side from the substrate 6) is covered with the second epitaxial layer 11B.

The first epitaxial layer 11A and the second epitaxial layer 11B correspond to the semiconductor layer 7. By forming the second epitaxial layer 11B, a semiconductor wafer structure 12 including the substrate 6 and the semiconductor layer 7 is formed. The semiconductor wafer structure 12 includes a first wafer main surface 93 corresponding to the first main surface 3 and a second wafer main surface 94 corresponding to the second main surface 4.

Next, as shown in FIG. 5E, a p-type impurity is selectively introduced into a surface of the second epitaxial layer 11B through a third resist mask 63. As a result, a third introduction portion 15a is formed at a surface portion of the first wafer main surface 93 of the semiconductor wafer structure 12. Thereafter, the third resist mask 63 is removed.

Next, a fourth resist mask 64 (second mask) is formed on the surface of the second epitaxial layer 11B. In detail, as shown in FIG. 5F, a resist 500 is applied on the second epitaxial layer 11B, and a patterning mask PM is placed on the resist 500. By irradiating the resist 500 with light (for example, ultraviolet light, etc.) through the patterning mask PM, the resist 500 is exposed, and as a result, as shown in FIG. 5G, the fourth resist mask 64 with an opening 64a having the same pattern as the opening pattern OP of the patterning mask PM is formed. The opening 64a of the fourth resist mask 64 corresponds to a region where the n-type drift region 21 is to be formed. The patterning mask PM is retracted from above the first epitaxial layer 11A.

The pattern of the opening 64a of the fourth resist mask 64 is the same as the pattern of the opening 62a of the second resist mask 62. As shown in FIG. 2, in the semiconductor device 1, the n-type drift region 21 and the p-type resurf layer 23 overlap each other when viewed from the thickness direction (normal direction Z) of the substrate 6. Therefore, the opening pattern of the opening 64a of the fourth resist mask 64 is made the same as the opening pattern of the opening 62a of the second resist mask 62. Then, in this embodiment, the opening pattern of the opening 64a of the fourth resist mask 64 is patterned through the same patterning mask PM as the opening pattern of the opening 62a of the second resist mask 62.

As shown in FIG. 5G, an n-type impurity is selectively introduced into the surface of the second epitaxial layer 11B through the fourth resist mask 64. As a result, a fourth introduction portion 21e is formed at the surface portion of the first wafer main surface 93 of the semiconductor wafer structure 12. Thereafter, the fourth resist mask 64 is removed. Examples of the n-type impurity may include P (phosphorus), As (arsenic), and the like.

Next, as shown in FIG. 5H, a p-type impurity is selectively introduced into the surface of the second epitaxial layer 11B through a fifth resist mask 65. As a result, a fifth introduction portion 22e is formed at the surface portion of the first wafer main surface 93 of the semiconductor wafer structure 12. Thereafter, the fifth resist mask 65 is removed.

Next, as shown in FIG. 5I, by heat-treating the semiconductor wafer structure 12, the p-type impurities of the third introduction portion 15a and the fifth introduction portion 22e and the n-type impurity of the fourth introduction portion 21e diffuse into the semiconductor wafer structure 12. As a result, a second pillar region 15 is formed from the third introduction portion 15a, the n-type drift region 21 is formed from the fourth introduction portion 21e, and the p-type body region 22 is formed from the fifth introduction portion 22e. Specifically, the n-type drift region 21 is formed such that its side portion 21b is flush with the side portion 23b of the p-type resurf layer 23. Further, the p-type body region 22 is formed adjacent to the n-type drift region 21 with an interval in the first direction X. The bottom 22a of the p-type body region 22 is located at the same depth as the bottom 21a of the n-type drift region 21 in the thickness direction (normal direction Z) of the substrate 6.

Next, as shown in FIG. 5J, the field insulating film 17 is formed over the first wafer main surface 93 of the semiconductor wafer structure 12 by a CVD method or a thermal oxidation treatment method. Next, the first wafer main surface 93 exposed through the first opening 17a, the second opening 17b, and the third opening 17c of the field insulating film 17 is thermally oxidized. As a result, the gate insulating film 28 is formed.

Next, the gate electrode 29 is formed. For example, a base electrode layer (in this embodiment, a conductive polysilicon layer) for the gate electrode 29 is formed by a CVD method so as to cover the field insulating film 17 and the gate insulating film 28. Next, unnecessary portions of the base electrode layer are removed by etching through a resist mask (not shown), thereby forming the gate electrode 29. The etching at this time may be wet etching or dry etching.

Next, as shown in FIG. 5K, an n-type impurity is selectively introduced into the surface portion of the p-type body region 22 using a resist mask (not shown) and the gate electrode 29 as masks. As a result, the n-type source region 26 is formed at the surface portion of each body region 22 in a self-aligned manner with respect to the gate electrode 29. Further, the sidewall 31 covering the sidewall of the gate electrode 29 is formed. In a process of forming the sidewall 31, for example, a base insulating film (not shown) for the sidewall 31 is formed over the field insulating film 17 so as to cover the gate electrode 29. Next, the base insulating film is selectively removed by etching, such as dry etching, so that a portion of the base insulating film that covers the sidewall of the gate electrode 29 remains.

Next, as shown in FIG. 5L, n-type impurities are selectively introduced into the surface portion of the n-type drift region 21 and the surface portion of the p-type body region 22 through a resist mask (not shown), the field insulating film 17, and the sidewall 31. As a result, the n-type drain region 25 is formed in a self-aligned manner with respect to the field insulating film 17, and the high concentration portion 27 is formed in a self-aligned manner with respect to the sidewall 31. Next, a p-type impurity is selectively introduced into the surface portion of the p-type body region 22 through a resist mask (not shown) and the field insulating film 17. As a result, the contact region 24 is formed in a self-aligned manner with respect to the field insulating film 17.

Next, as shown in FIG. 5M, the interlayer insulating film 34 is formed to cover the field insulating film 17 and the gate electrode 29 by, for example, a CVD method. Next, unnecessary portions of the interlayer insulating film 34 are removed by etching through a resist mask (not shown). As a result, the plurality of drain openings 35, the plurality of source openings 36, the plurality of back gate openings 37, and the gate opening 38 (not shown in FIG. 5M) are formed at the interlayer insulating film 34.

Next, by, for example, a sputtering method, a Ti-based metal film (at least one selected from the group of a Ti film and a TiN film) is formed in a film shape along wall surfaces of the plurality of drain openings 35, wall surfaces of the plurality of source openings 36, wall surfaces of the plurality of back gate openings 37, a wall surface of the gate opening 38, and a main surface of the interlayer insulating film 34. Next, a tungsten (W) film is formed to cover the Ti-based metal film by, for example, a CVD method. The tungsten film is buried in the plurality of drain openings 35, the plurality of source openings 36, the plurality of back gate openings 37, and the gate opening 38, with the Ti-based metal film in between, and covers the main surface of the interlayer insulating film 34 with the Ti film in between.

Thereafter, unnecessary portions of the tungsten film and unnecessary portions of the Ti-based metal film are removed by etching. As a result, the drain contact electrode 41, the source contact electrode 42, the back gate contact electrode 43, and the gate contact electrode 44 (not shown in FIG. 5M) are formed.

Next, a conductive material for wiring is formed over the interlayer insulating film 34 by, for example, a sputtering method. Next, unnecessary portions of the conductive material are removed by etching through a resist mask (not shown). As a result, the drain wiring 45, the source wiring 46, the back gate wiring 47, and the gate wiring (not shown) are formed over the interlayer insulating film 34.

Thereafter, the semiconductor wafer structure 12 is cut along the planned cutting lines. As a result, a plurality of semiconductor devices 1 are cut out from one semiconductor wafer structure 12.

It may also be possible to form the p-type resurf layer 23 by introducing the p-type impurity from the first wafer main surface 93 of the semiconductor wafer structure 12. However, since there is a distance from the first wafer main surface 93 to the formation position of the p-type resurf layer 23, it is necessary to introduce the p-type impurity to a deep position. In this case, the positional accuracy and dimensional accuracy of the resurf layer 23 formed at the semiconductor wafer structure 12 may be low.

However, in this embodiment, the formation of the epitaxial layers is divided into two stages of forming the first epitaxial layer 11A and forming the second epitaxial layer 11B, and the p-type resurf layer 23 is formed at a surface of the first epitaxial layer 11A. As a result, the positional accuracy and dimensional accuracy of the resurf layer 23 formed at the semiconductor wafer structure 12 may be improved.

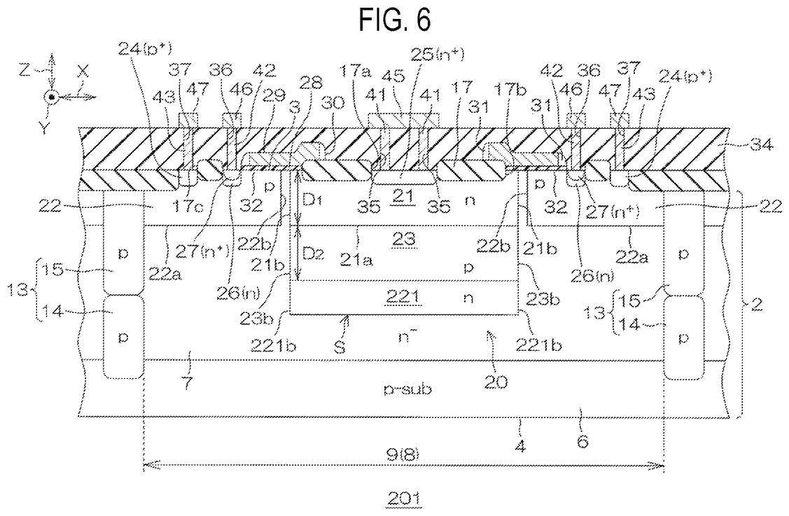

FIG. 6 is a cross-sectional diagram of a semiconductor device 201 according to a second embodiment of the present disclosure. In the second embodiment, only portions that are mainly different from the first embodiment are described, and the same components as those described so far are denoted by the same reference numerals, and the explanation thereof is omitted.

The semiconductor device 201 further includes an n-type (second conductivity type) buried layer 221 formed below the p-type resurf layer 23. The semiconductor device 201 includes a stacked structure S of the buried layer 221, the p-type resurf layer 23, and the n-type drift region 21 in the thickness direction (normal direction Z) of the substrate 6. In the stacked structure S, the p-type resurf layer 23 is sandwiched between the n-type drift region 21 and the n-type buried layer 221 in the thickness direction of the substrate 6.

The n-type buried layer 221 is formed near the second main surface 4 with respect to the p-type resurf layer 23. The n-type buried layer 221 may be in contact with the p-type resurf layer 23. The n-type buried layer 221 overlaps the n-type drift region 21 and the p-type resurf layer 23 in a plan view. That is, the n-type buried layer 221 is formed in an elongated shape along the second direction Y in a plan view. The n-type buried layer 221 does not reach a boundary between the substrate 6 and the semiconductor layer 7.

A side portion 221b of the n-type buried layer 221 and the side portion 23b of the p-type resurf layer 23 are flush with each other. In other words, the side portion 221b of the n-type buried layer 221 and the side portion 23b of the p-type resurf layer 23 are continuous in the thickness direction (normal direction Z) of the substrate 6. The n-type buried layer 221 may have a higher n-type impurity concentration than the semiconductor layer 7. The n-type impurity concentration of the n-type buried layer 221 may be, for example, 1.0×10¹⁶ cm⁻³ or more and 1.0×10¹⁸ cm⁻³ or less. A thickness D₃ of the n-type buried layer 221 may be smaller than the thickness D₁ of the n-type drift region 21 and the thickness D₂ of the p-type resurf layer 23, for example.

When increasing the n-type impurity concentration of the n-type drift region 21 in order to reduce the on-resistance, it is conceivable to make the p-type impurity concentration of the p-type resurf layer 23 as high as the n-type impurity concentration of the n-type drift region 21 in order to prevent electric field concentration from occurring in the n-type drain region 25. However, increasing the n-type impurity concentration of the n-type drift region 21 may impede the effect of alleviating the electric field concentration.

By sandwiching the p-type resurf layer 23 between the n-type drift region 21 and the n-type buried layer 221 in the thickness direction (normal direction Z) of the substrate 6, a depletion layer can be effectively expanded. This can prevent the electric field concentration from occurring in the n-type drain region 25. As a result, it possible to reduce the on-resistance while maintaining the breakdown voltage of the semiconductor device 201 even higher.

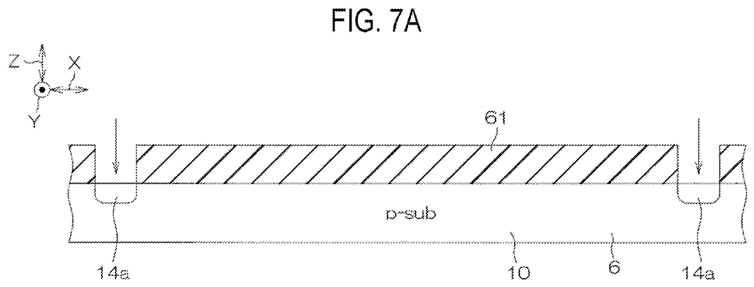

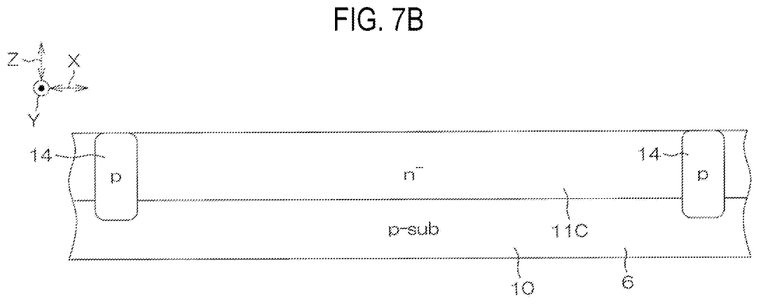

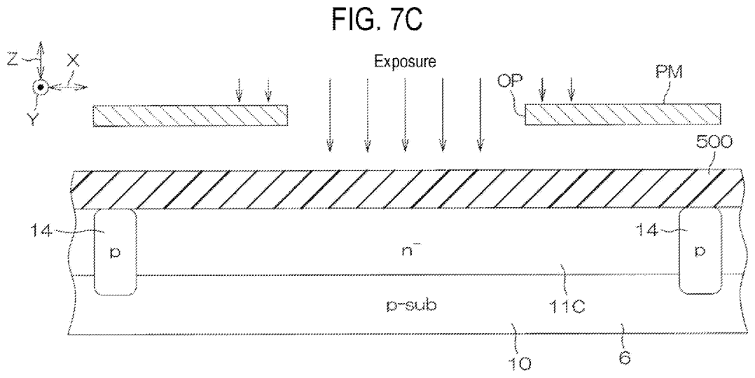

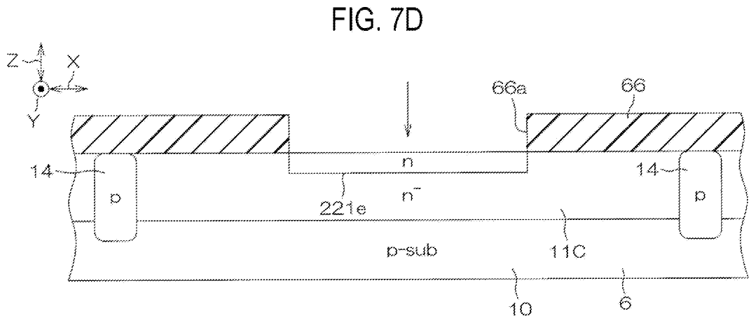

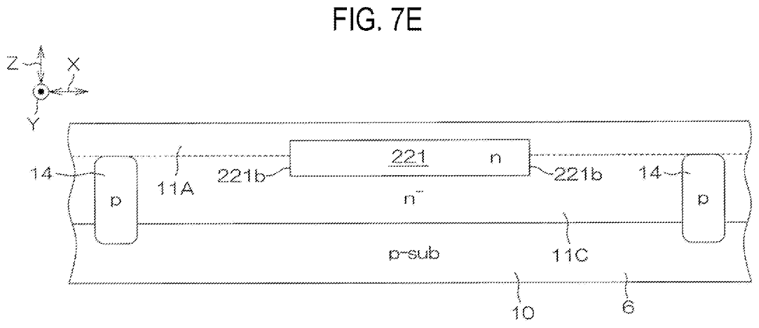

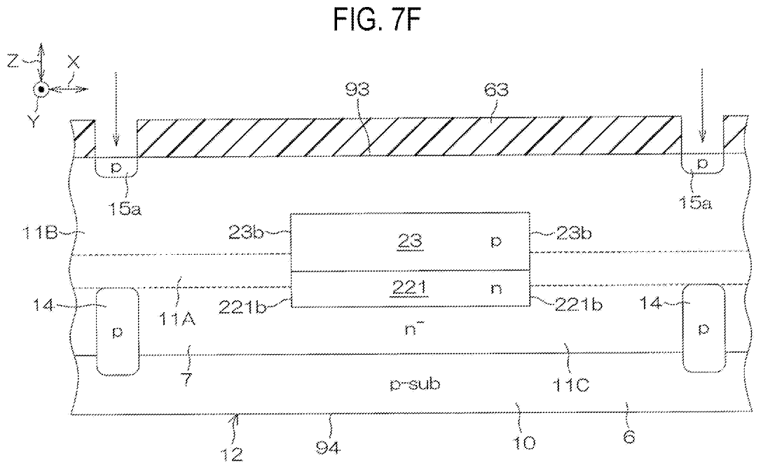

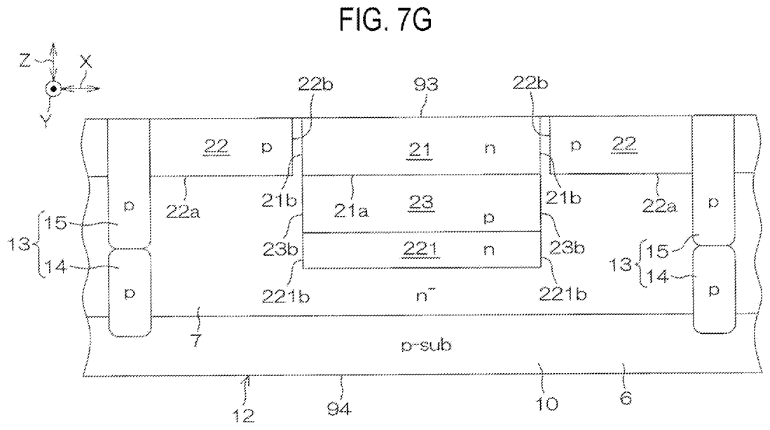

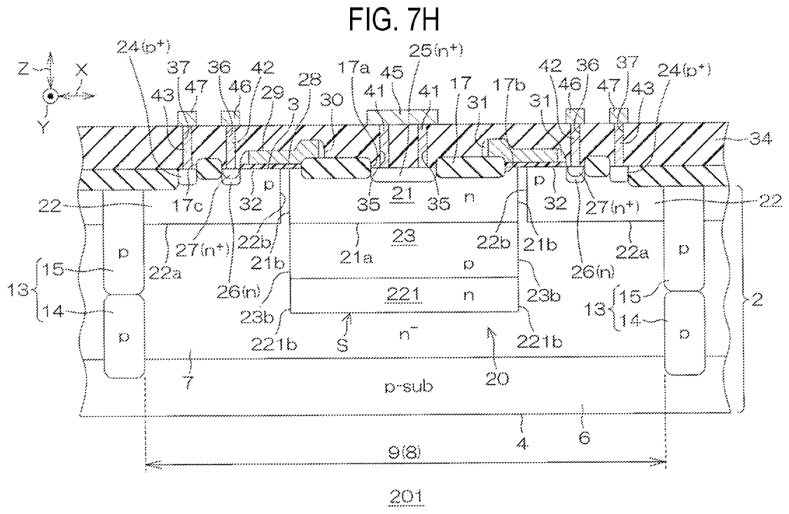

FIGS. 7A to 7H are diagrams showing parts of a process of manufacturing the semiconductor device 201 according to the second embodiment of the present disclosure. Note that in FIGS. 7A to 7H, among the reference numerals shown in FIG. 6, reference numerals for components necessary for explaining the process of manufacturing the semiconductor device 201 are mainly used, and other reference numerals may be omitted.

As shown in FIG. 7A, the p-type semiconductor wafer 10 is prepared. The planned cutting lines of the device regions are set on the semiconductor wafer 10 to partition regions that will become individual semiconductor devices 201. The semiconductor wafer 10 corresponds to the substrate 6 of the semiconductor device 201. Next, the p-type impurity is selectively introduced into the surface portion of the main surface of the semiconductor wafer 10 through the first resist mask 61. As a result, the first introduction portion 14a is formed at the surface portion of the main surface of the semiconductor wafer 10. Thereafter, the first resist mask 61 is removed from the semiconductor wafer 10. Examples of the p-type impurity (first impurity) may include B (boron), Al (aluminum), and the like.

Next, as shown in FIG. 7B, a semiconductor material, such as Si or SiC, is epitaxially grown from the main surface of the semiconductor wafer 10 by an epitaxial growth method to form an n-type third epitaxial layer 11C. At this time, the p-type impurity of the first introduction portion 14a introduced into the main surface of the semiconductor wafer 10 diffuses into the n-type third epitaxial layer 11C. As a result, the p-type first pillar region 14 is formed.

Next, a sixth resist mask 66 (third mask) is placed on the third epitaxial layer 11C. In detail, as shown in FIG. 7C, the resist 500 is applied on the third epitaxial layer 11C, and a patterning mask PM is placed on the resist 500. The patterning mask PM has a predetermined opening pattern OP. By irradiating the resist 500 with light (for example, ultraviolet light, etc.) through the patterning mask PM, the resist 500 is exposed, and a portion of the resist 500 exposed through the opening pattern OP is removed. As a result, as shown in FIG. 7D, the sixth resist mask 66 with an opening 66a having the same pattern as the opening pattern OP of the patterning mask PM is formed. The opening 66a of the sixth resist mask 66 corresponds to a region where the buried layer 221 is to be formed. The patterning mask PM is retracted from above the third epitaxial layer 11C.

The pattern of the opening 66a of the sixth resist mask 66 is the same as the pattern of the openings 62a of the second resist mask 62. In the semiconductor device 201, the buried layer 221 and the p-type resurf layer 23 overlap each other when viewed from the thickness direction (normal direction Z) of the substrate 6. Therefore, the opening pattern of the opening 66a of the sixth resist mask 66 is made the same as the opening pattern of the opening 62a of the second resist mask 62. Then, in this embodiment, the opening pattern of the opening 66a of the sixth resist mask 66 is patterned through the same patterning mask PM as the opening pattern of the opening 62a of the second resist mask 62.

Next, as shown in FIG. 7D, an n-type impurity is selectively introduced into a surface portion of the third epitaxial layer 11C through the sixth resist mask 66. As a result, a sixth introduction portion 221e is formed at the surface portion of the main surface of the semiconductor wafer 10. Thereafter, the sixth resist mask 66 is removed from the semiconductor wafer 10.

Next, as shown in FIG. 7E, a semiconductor material, such as Si or SiC, is epitaxially grown from a main surface of the third epitaxial layer 11C by an epitaxial growth method to form the n-type first epitaxial layer 11A. At this time, the n-type impurity of the sixth introduction portion 221e introduced into the main surface of the semiconductor wafer 10 diffuses into the first epitaxial layer 11A in the thickness direction (normal direction Z) of the substrate 6. As a result, the n-type buried layer 221 is formed. A surface of the n-type buried layer 221 (the surface on the opposite side from the substrate 6) is covered with the first epitaxial layer 11A.

Next, as shown in FIG. 7F, a semiconductor material, such as Si or SiC, is epitaxially grown from the main surface of the first epitaxial layer 11A by an epitaxial growth method to form the n-type second epitaxial layer 11B. At this time, the p-type impurity of the second introduction portion 23e introduced into the main surface of the semiconductor wafer 10 diffuses into the second epitaxial layer 11B in the thickness direction (normal direction Z) of the substrate 6. As a result, the p-type resurf layer 23 is formed. The p-type resurf layer 23 is formed so that its side portion 23b is continuous with the side portion 221b of the n-type buried layer 221 in the thickness direction (normal direction Z) of the semiconductor wafer structure 12. The surface of the p-type resurf layer 23 (the surface on the opposite side from the substrate 6) is covered with the second epitaxial layer 11B.

The first epitaxial layer 11A, the second epitaxial layer 11B, and the third epitaxial layer 11C correspond to the semiconductor layer 7. By forming the second epitaxial layer 11B, the semiconductor wafer structure 12 including the substrate 6 and the semiconductor layer 7 is formed.

Next, similar to the step shown in FIG. 5E, p-type impurities are selectively introduced into the surface of the second epitaxial layer 11B, and the third introduction portion 15a is formed at the surface portion of the first wafer main surface 93. Next, similar to the step shown in FIG. 5G, n-type impurities are selectively introduced into the surface of the second epitaxial layer 11B, and the fourth introduction portion 21e is formed at the surface portion of the first wafer main surface 93. Next, similar to the step shown in FIG. 5H, p-type impurities are selectively introduced into the surface of the second epitaxial layer 11B, and the fifth introduction portion 22e is formed at the surface portion of the first wafer main surface 93.

Next, as shown in FIG. 7G, by heat-treating the semiconductor wafer structure 12, the p-type impurities of the third introduction portion 15a and the fifth introduction portion 22e and the n-type impurity of the fourth introduction portion 21e diffuse into the semiconductor wafer structure 12. As a result, the second pillar region 15 is formed from the third introduction portion 15a, the n-type drift region 21 is formed from the fourth introduction portion 21e, and the p-type body region 22 is formed from the fifth introduction portion 22e.

The subsequent steps are the same as the manufacturing steps of the first embodiment, so the explanation thereof will be omitted. As shown in FIG. 7H, after forming the drain wiring 45, the source wiring 46, the back gate wiring 47, and the gate wiring (not shown) on the interlayer insulating film 34, the semiconductor wafer 2 structure 12 is cut along the planned cutting lines. As a result, a plurality of semiconductor devices 201 are cut out from one semiconductor wafer structure 12.

It may be also possible to form the p-type resurf layer 23 by introducing the p-type impurity from the first wafer main surface 93 of the semiconductor wafer structure 12. However, since there is a distance from the first wafer main surface 93 to the formation position of the p-type resurf layer 23, it is necessary to introduce the p-type impurity to a deep position. In this case, the positional accuracy and dimensional accuracy of the p-type resurf layer 23 formed at the semiconductor wafer structure 12 may be low.

However, in this embodiment, the formation of the epitaxial layers is divided into two stages of forming the first epitaxial layer 11A and forming the second epitaxial layer 11B, and the p-type resurf layer 23 is formed at the surface of the first epitaxial layer 11A. As a result, the positional accuracy and dimensional accuracy of the p-type resurf layer 23 formed at the semiconductor wafer structure 12 may be improved.

Although a plurality of embodiments of the present disclosure have been described above, the present disclosure can also be implemented in other forms.

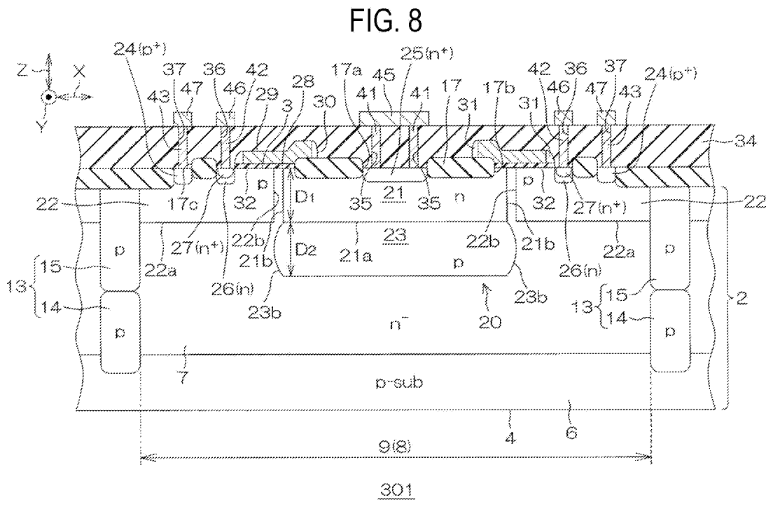

For example, as shown in a semiconductor device 301 of FIG. 8, the side portion 23b of the p-type resurf layer 23 is not linear in a cross-sectional view, but may bulge convexly in the first direction X and the second direction Y. In this case, the side portion 23b of the resurf layer 23 may be continuous with the side portion 21b of the drift region 21 such that it bulges in the lateral direction along the first main surface 3 from a lower end of the side portion 21b of the drift region 21. The side portion 23b of the resurf layer 23 may be located in a region more inner than the side portion 22b of the body region 22. Further, although not shown, the side portion 221b of the buried layer 221 in FIG. 6 may not be linear in a cross-sectional view, but may bulge convexly in the first direction X and the second direction Y.

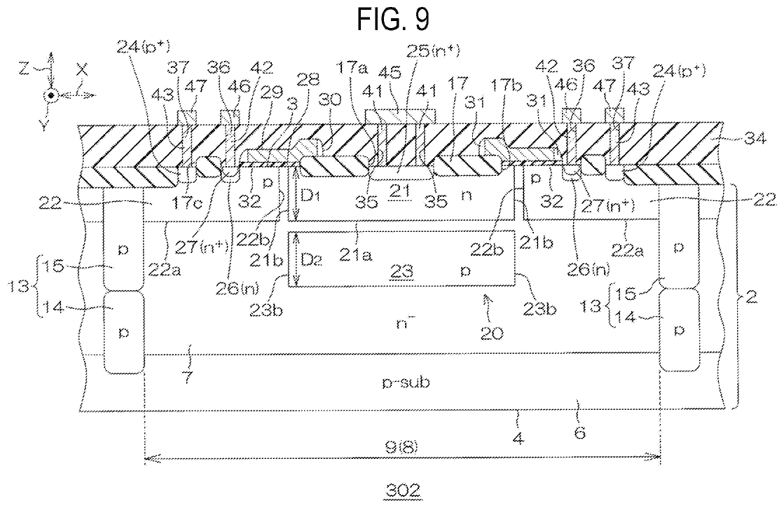

Further, as shown in a semiconductor device 302 of FIG. 9, the p-type resurf layer 23 may be separated from the drift region 21 in the thickness direction (normal direction Z) of the substrate 6. Further, although not shown, the n-type buried layer 221 may be separated from the p-type resurf layer 23 in the thickness direction (normal direction Z) of the substrate 6.

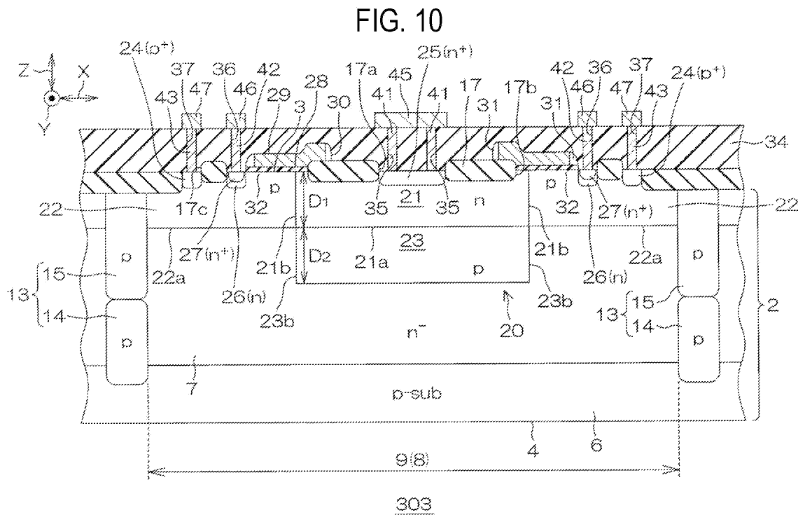

Further, as shown in a semiconductor device 303 of FIG. 10, the n-type drift region 21 and the p-type body region 22 may be in contact with each other.

Further, for example, a configuration may be adopted in which the conductivity type of each semiconductor portion of the semiconductor devices 1, 201, 301, 302, and 303 is reversed. For example, in the semiconductor devices 1, 201, 301, 302, and 303, the p-type (first conductivity type) portion may be n-type, and the n-type (second conductivity type) portion may be p-type.

The features described below can be extracted from the description of the present disclosure and the drawings.

### Supplementary Note 1-1

A semiconductor device (1, 201, 301, 302, 303) including:
a first conductivity type substrate (6);
a second conductivity type semiconductor layer (7) formed over the substrate (6);
a second conductivity type drift region (21) formed at a surface portion of the semiconductor layer (7);
a second conductivity type drain region (25) formed at the drift region (21);
a first conductivity type body region (22) formed adjacent to the drift region (21) at the surface portion of the semiconductor layer (7);
a second conductivity type source region (26) formed at the body region (22); and
a first conductivity type resurf layer (23) that expands from a center (C) of the drain region (25) to both sides in a lateral direction along a main surface (3) of the semiconductor device to entirely cover the drift region (21).

According to this configuration, the first conductivity type resurf layer (23) is formed to cover the second conductivity type drift region (21). The first conductivity type resurf layer (23) expands from the center (C) of the second conductivity type drain region (25) to both sides in the lateral direction along the main surface (3) to entirely cover the drift region (21). By forming such a first conductivity type resurf layer (23), it is possible to prevent electric field concentration from occurring in the second conductivity type drain region (25). This makes it possible to achieve a high breakdown voltage.

### Supplementary Note 1-2

The semiconductor device (1, 201, 301, 302, 303) of Supplementary Note 1-1, wherein a side portion (23b) of the resurf layer (23) and a side portion (21b) of the drift region (21) are continuous in a thickness direction (Z) of the substrate (6).

### Supplementary Note 1-3

The semiconductor device (1, 201, 302, 303) of Supplementary Note 1-2, wherein the side portion (23b) of the resurf layer (23) and the side portion (21b) of the drift region (21) are flush with each other.

### Supplementary Note 1-4

The semiconductor device (1, 201, 301, 303) of any one of Supplementary Notes 1-1 to 1-3, wherein the resurf layer (23) is in contact with the drift region (21).

### Supplementary Note 1-5

The semiconductor device (302) of any one of Supplementary Notes 1-1 to 1-3, wherein the resurf layer (23) is separated from the drift region (21).

### Supplementary Note 1-6

The semiconductor device (201) of any one of Supplementary Notes 1-1 to 1-5, further including: a second conductivity type buried layer (221) formed below the resurf layer (23).

### Supplementary Note 1-7

The semiconductor device (201) of Supplementary Note 1-6, wherein a side portion (221b) of the buried layer (221) and the side portion (23b) of the resurf layer (23) are flush with each other.

### Supplementary Note 1-8

The semiconductor device (201) of Supplementary Note 1-6 or 1-7, further including: a stacked structure (S) of the buried layer (221), the resurf layer (23), and the drift region (21), in the thickness direction (Z) of the substrate (6).

### Supplementary Note 1-9

The semiconductor device (303) of any one of Supplementary Notes 1-1 to 1-8, wherein the drift region (21) and the body region (22) are in contact with each other.

### Supplementary Note 1-10

The semiconductor device (1, 201, 301, 302) of any one of Supplementary Notes 1-1 to 1-8, wherein the drift region (21) and the body region (22) are separated from each other.

### Supplementary Note 1-11

A method of manufacturing a semiconductor device (1, 201, 301, 302, 303), including: forming a second conductivity type first epitaxial layer (11A) over a first conductivity type substrate (6);
forming a first conductivity type resurf layer (23) by selectively introducing a first conductivity type first impurity into a surface of the first epitaxial layer (11A);
forming a second conductivity type second epitaxial layer (11B) to cover the resurf layer (23);
forming a second conductivity type drift region (21) having a concentration higher than a concentration of the second epitaxial layer (11B) by selectively introducing a second conductivity type second impurity into a surface of the second epitaxial layer (11B) such that a side portion (21b) of the drift region (21) and a side portion (23b) of the resurf layer (23) are continuous in a thickness direction (Z) of the substrate (6);
forming a first conductivity type body region (22) adjacent to the drift region (21) by selectively introducing a first conductivity type impurity into the surface of the second epitaxial layer (11B); and
forming a second conductivity type drain region (25) having a concentration higher than a concentration of the drift region (21) by selectively introducing a second conductivity type impurity into a surface of the drift region (21).

According to this method, the first conductivity type resurf layer (23) is formed by selectively introducing the first conductivity type first impurity into the surface of the second conductivity type first epitaxial layer (11A). Then, the second conductivity type second epitaxial layer (11B) is formed to cover the first conductivity type resurf layer (23), and the second conductivity type drift region (21) is formed by selectively introducing the second conductivity type second impurity into the surface of the second epitaxial layer (11B) such that the side portion (21b) of the drift region (21) and the side portion (23b) of the resurf layer (23) are continuous in the thickness direction (Z) of the substrate (6). As a result, it is possible to manufacture the semiconductor device (1, 201, 301, 302, 303) including the resurf layer (23) that expands from a center (C) of a second conductivity type drain region (25) to both sides in a lateral direction along a main surface (3) to entirely cover the drift region (21). Therefore, it is possible to manufacture the semiconductor device (1, 201, 301, 302, 303) that can achieve a high breakdown voltage.

Further, according to this method, the formation of the epitaxial layers is divided into two stages of forming the first epitaxial layer (11A) and forming the second epitaxial layer (11B). Then, the resurf layer (23) is formed at the surface of the first epitaxial layer (11A). As a result, it is possible to improve the positional accuracy and dimensional accuracy of the resurf layer (23).

### Supplementary Note 1-12

The method of Supplementary Note 1-11, wherein the first impurity is introduced into the first epitaxial layer (11A) through a first mask (62) which is patterned through a patterning mask (PM) having a predetermined opening pattern, and
wherein the second impurity is introduced into the second epitaxial layer (11B) through a second mask (64) which is patterned through the patterning mask (PM).

### Supplementary Note 1-13

The method of Supplementary Note 1-11, further including:
forming a second conductivity type third epitaxial layer (11C) over the substrate (6) prior to forming the first epitaxial layer (11A); and
forming a second conductivity type buried layer (221) by selectively introducing a second conductivity type third impurity into a surface of the third epitaxial layer (11C),
wherein the resurf layer (23) is formed such that the side portion (23b) of the resurf layer (23) and a side portion (221b) of the buried layer (221) are continuous in the thickness direction (Z) of the substrate (6).

### Supplementary Note 1-14

The method of Supplementary Note 1-13, wherein the third impurity is introduced into the third epitaxial layer (11C) through a third mask (66) which is patterned through a patterning mask (PM) having a predetermined opening pattern,
wherein the first impurity is introduced into the first epitaxial layer (11A) through a first mask (62) which is patterned through the patterning mask (PM), and
wherein the second impurity is introduced into the second epitaxial layer (11B) through a second mask (64) which is patterned through the patterning mask (PM).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first conductivity type substrate;
a second conductivity type semiconductor layer formed over the substrate;
a second conductivity type drift region formed at a surface portion of the semiconductor layer;
a second conductivity type drain region formed at the drift region;
a first conductivity type body region formed adjacent to the drift region at the surface portion of the semiconductor layer;
a second conductivity type source region formed at the body region; and
a first conductivity type resurf layer that expands from a center of the drain region to both sides in a lateral direction along a main surface of the semiconductor device to entirely cover the drift region.

2. The semiconductor device of claim 1, wherein a side portion of the resurf layer and a side portion of the drift region are continuous in a thickness direction of the substrate.

3. The semiconductor device of claim 2, wherein the side portion of the resurf layer and the side portion of the drift region are flush with each other.

4. The semiconductor device of claim 1, wherein the resurf layer is in contact with the drift region.

5. The semiconductor device of claim 1, wherein the resurf layer is separated from the drift region.

6. The semiconductor device of claim 1, further comprising: a second conductivity type buried layer formed below the resurf layer.

7. The semiconductor device of claim 6, wherein a side portion of the buried layer and a side portion of the resurf layer are flush with each other.

8. The semiconductor device of claim 6, further comprising: a stacked structure of the buried layer, the resurf layer, and the drift region, in a thickness direction of the substrate.

9. The semiconductor device of claim 1, wherein the drift region and the body region are in contact with each other.

10. The semiconductor device of claim 1, wherein the drift region and the body region are separated from each other.

11. A method of manufacturing a semiconductor device, comprising:
forming a second conductivity type first epitaxial layer over a first conductivity type substrate;
forming a first conductivity type resurf layer by selectively introducing a first conductivity type first impurity into a surface of the first epitaxial layer;
forming a second conductivity type second epitaxial layer to cover the resurf layer;
forming a second conductivity type drift region having a concentration higher than a concentration of the second epitaxial layer by selectively introducing a second conductivity type second impurity into a surface of the second epitaxial layer such that a side portion of the drift region and a side portion of the resurf layer are continuous in a thickness direction of the substrate;
forming a first conductivity type body region adjacent to the drift region by selectively introducing a first conductivity type impurity into the surface of the second epitaxial layer; and
forming a second conductivity type drain region having a concentration higher than a concentration of the drift region by selectively introducing a second conductivity type impurity into a surface of the drift region.

12. The method of claim 11, wherein the first impurity is introduced into the first epitaxial layer through a first mask which is patterned through a patterning mask having a predetermined opening pattern, and
wherein the second impurity is introduced into the second epitaxial layer through a second mask which is patterned through the patterning mask.

13. The method of claim 11, further comprising:
forming a second conductivity type third epitaxial layer over the substrate prior to forming the first epitaxial layer; and
forming a second conductivity type buried layer by selectively introducing a second conductivity type third impurity into a surface of the third epitaxial layer,
wherein the resurf layer is formed such that the side portion of the resurf layer and a side portion of the buried layer are continuous in the thickness direction of the substrate.

14. The method of claim 13, wherein the third impurity is introduced into the third epitaxial layer through a third mask which is patterned through a patterning mask having a predetermined opening pattern,
wherein the first impurity is introduced into the first epitaxial layer through a first mask which is patterned through the patterning mask, and
wherein the second impurity is introduced into the second epitaxial layer through a second mask which is patterned through the patterning mask.
